(19) United States
(12) Patent Application Publication
(10) Pub. No.: US 2009/0163028 A1
(43) Pub. Date: Jun. 25, 2009

(54) METHOD FOR FABRICATING SEMICONDUCTOR DEVICE

(75) Inventor: Tae-Woo JUNG, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/163,960

(22) Filed: Jun. 27, 2008

(30) Foreign Application Priority Data
Dec. 24, 2007 (KR) 10-2007-0136671

(51) Int. Cl. H01L 21/311

(52) U.S. Cl. 438/703; 257/E21.249

(57) ABSTRACT

A method for fabricating a semiconductor device includes forming an organic bottom anti-reflective coating over an etch target layer, forming a photoresist pattern over the organic bottom anti-reflective coating, and etching the organic bottom anti-reflective coating using a sulfur-containing gas.

### CROSS-REFERENCE TO RELATED APPLICATIONS

The present invention claims priority of Korean patent application number 2007-0136671, filed on Dec. 24, 2007, which is incorporated by reference in its entirety.

### BACKGROUND OF THE INVENTION

The present invention relates to a semiconductor device, and more particularly, to a method for etching an organic bottom anti-reflective coating (BARC) of a semiconductor device using a photoresist pattern.

As is well known, a photoresist layer is used in a mask process for forming patterns. A photoresist layer is coated and the coated photoresist layer is patterned using an exposure process and development process. At this point, a BARC is used in the bottom of the photoresist layer in order to prevent light reflection in the exposure process. Examples of the BARC include an inorganic BARC and an organic BARC.

When an organic BARC is applied to the bottom of the photoresist layer, several mixed gases are used to etch the organic BARC. The mixed gases may include a mixed gas of tetrafluoromethane (CF₄), fluoroform (CHF₃), and oxygen (O₂); a mixed gas of chlorine (Cl₂), hydrogen bromide (HBr), and nitrogen (N₂); or a mixed gas of HBr and O₂.

FIG. 1 illustrates images of a photoresist pattern where an organic BARC is etched using a mixed gas of CF₄, CHF₃, and O₂.

Referring to FIG. 1, breaks occur in the middle of a photoresist pattern along with line width roughness (LWR) or line edge roughness (LER), leading to distortion of the photoresist pattern. This is because fluorine (F) penetrates the photoresist pattern and thus the photoresist pattern is easily broken due to its weakened bonding force, causing stress in the photoresist pattern.

If such a damaged photoresist pattern is used in a subsequent process, the pattern may break. Furthermore, fabrication failure may be caused in the subsequent process due to severe bending of the photoresist pattern (i.e., leaning of the sidewalls of the photoresist pattern). Furthermore, as the design rule decreases, the above-described limitations become more severe.

FIG. 2 illustrates images of a photoresist pattern when an organic BARC is etched using a mixed gas of HBr and O₂.

Referring to FIG. 2, the height of the photoresist pattern is significantly lower compared with that of FIG. 1. If such a pattern is used in a subsequent process, the pattern may disappear due to an insufficient etch margin or contact open failure may occur.

FIG. 3 illustrates images of a photoresist pattern when an organic BARC is etched using a mixed gas of Cl₂, HBr, and N₂.

Referring to FIG. 3, the height of the photoresist pattern is increased, compared with that of FIG. 2, but is not uniform. The non-uniform height of the photoresist pattern causes it to break in a subsequent process. Furthermore, due to Cl₂ contained in the mixed gas, the photoresist pattern is bent (i.e., leaning of the sidewalls), degrading CD controllability in the fabrication process.

### SUMMARY OF THE INVENTION

Embodiments of the present invention relate to a method for fabricating a semiconductor device, which is capable of preventing distortion or loss of a photoresist pattern used as an etch barrier in a process of etching an organic BARC.

In accordance with an aspect of the present invention, there is provided a method for fabricating a semiconductor device. The method includes forming an organic bottom anti-reflective coating over an etch target layer, forming a photoresist pattern over the organic bottom anti-reflective coating, and etching the organic bottom anti-reflective coating using a sulfur-containing gas.

In accordance with another aspect of the present invention, there is provided a method for fabricating a semiconductor device. The method includes forming an organic bottom anti-reflective coating over an etch target layer, forming a photoresist pattern over the organic bottom anti-reflective coating, and etching the organic bottom anti-reflective coating using a mixed gas of a sulfur-containing gas.

### BRIEF DESCRIPTION OF THE DRAWINGS

FIG. 1 illustrates images of a photoresist pattern when an organic BARC is etched using a mixed gas of CF₄, CHF₃, and O₂.

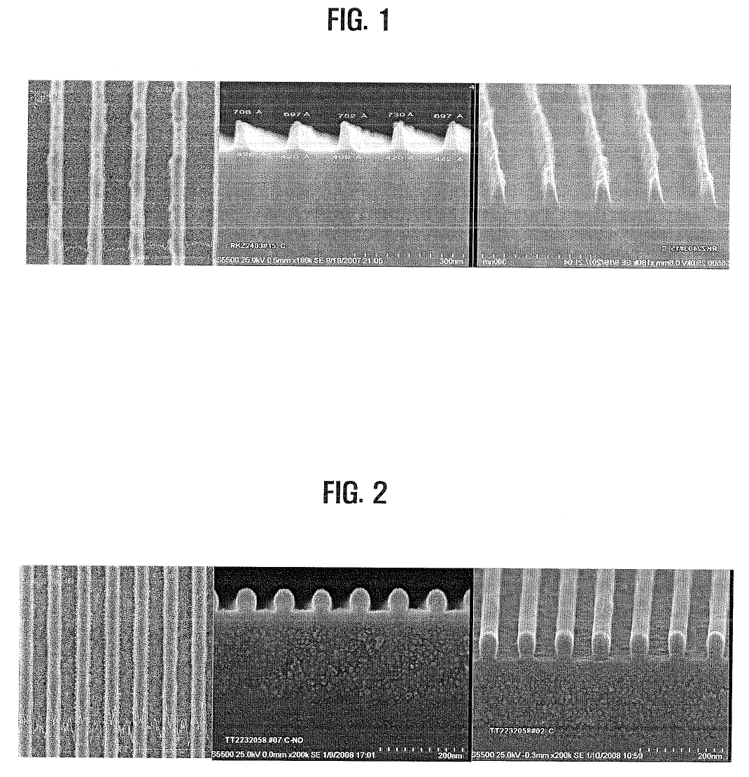

FIG. 2 illustrates images of a photoresist pattern when an organic BARC is etched using a mixed gas of HBr and O₂.

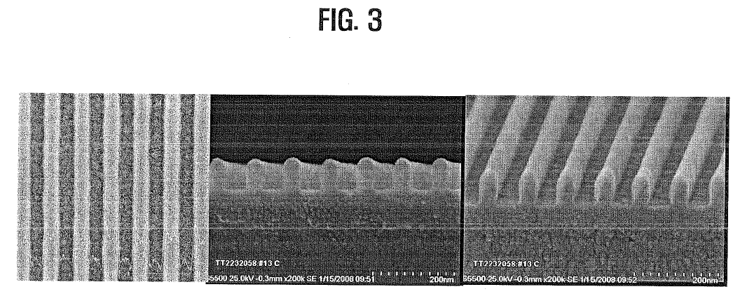

FIG. 3 illustrates images of a photoresist pattern when an organic BARC is etched using a mixed gas of Cl₂, HBr, and N₂.

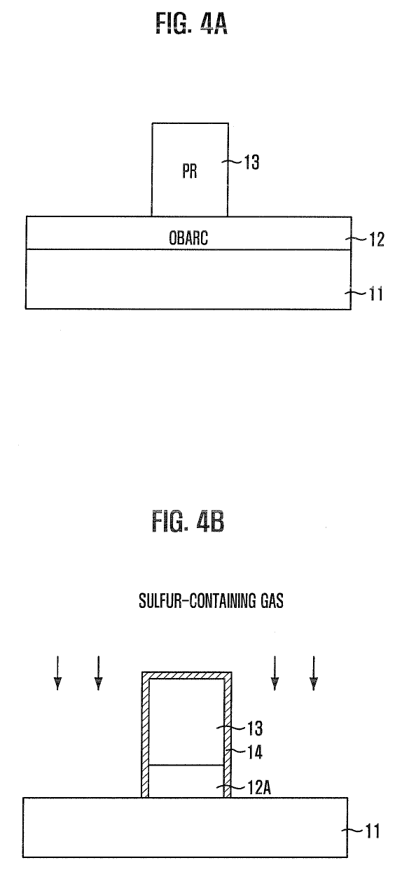

FIGS. 4A and 4B illustrate a method for etching an organic BARC in accordance with an embodiment of the present invention.

FIGS. 5A to 5C illustrate a method for fabricating a semiconductor device in accordance with a first embodiment of the present invention.

FIGS. 6A to 6C illustrate a method for fabricating a semiconductor device in accordance with a second embodiment of the present invention.

FIG. 7 illustrates photographs of a photoresist pattern in etching an organic BARC according to the embodiment of the present invention.

### DESCRIPTION OF SPECIFIC EMBODIMENTS

Hereinafter, a method for fabricating a semiconductor device in accordance with the present invention will be described in detail with reference to the accompanying drawings.

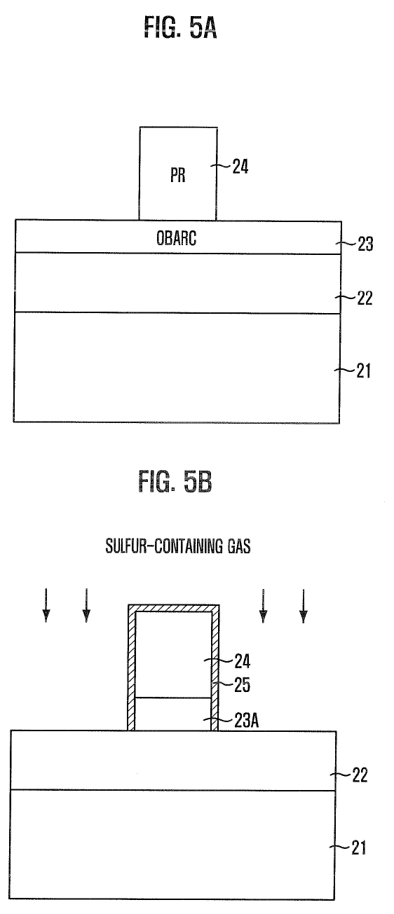

The present invention provides a method for fabricating a semiconductor device, which is capable of preventing distortion or loss of a photoresist pattern in a process of etching an organic bottom anti-reflective coating (BARC). To this end, a sulfur-containing gas or a mixed gas of a sulfur-containing gas is used to etch the organic BARC, which will be described below in detail with reference to FIGS. 4A and 4B.

FIGS. 4A and 4B illustrate a method for etching an organic BARC in accordance with an embodiment of the present invention.

Referring to FIG. 4A, an organic BARC 12 is formed over an etch target layer 11. The etch target layer 11 may be formed of dielectric or conductive material, and the etch target layer 11 may be a silicon substrate. The organic BARC 12 serves to prevent reflection in an exposure process of a subsequent photoresist layer.

A photoresist pattern 13 is formed over the organic BARC 12. The photoresist pattern 13 may be formed by coating a photoresist layer over the organic BARC 12 and patterning the coated photoresist layer through exposure and development processes.

Referring to FIG. 4B, the organic BARC 12 (see FIG. 4A) is etched using a sulfur-containing gas or a mixed gas of a sulfur-containing gas. That is, the etchant includes sulfur. At this point, the photoresist pattern 13 is used as an etch barrier. The sulfur-containing gas may include COS gas or sulfur dioxide (SO₂) gas. The sulfur-containing gas may also include a mixed gas of SO₂ and O₂.

In the case of the SO₂ gas, a sulfur (S) component of SO₂ reacts with the carbon-based photoresist pattern 13 and C═O═S or S═C═S bonding is formed on the surface of the photoresist pattern 13. In this case, a large amount of gas is needed because the COS or SCS bonding needs to be formed first when the photoresist pattern 13 reacts with SO₂.

In the case of the COS gas, the same effect as the case of the SO₂ gas can be obtained by using a small amount of gas, because the above reaction of the SO₂ gas is not needed. Therefore, the COS gas may be used as the sulfur-containing gas.

When the COS gas is used as the sulfur-containing gas, a mixed gas may include COS and one or more gases selected from the group consisting of tetrachlorosilane (SiCl₄), argon (Ar), helium (He), O₂, N₂, carbon monoxide (CO), xenon (Xe), and krypton (Kr) in order to increase the etch efficiency. In order to reduce the LWR and the LER, HBr or Cl₂ may be further added to the mixed gas including COS and one or more gases selected from the group consisting of SiCl₄, Ar, He, O₂, N₂, CO, Xe, and Kr.

The COS gas used in etching the organic BARC 12 may be produced by the following reaction formula:

SO₂+3CO→COS+2CO₂

2CO+S₂→2COS

From the above reaction formula, COS may be produced through the reaction of SO₂ and 3CO or the reaction of 2CO and S₂. That is, since COS has been formed already, another reaction is not needed. Since COS can be adsorbed into the surface of the photoresist pattern 13, the protection effect of the photoresist pattern 13 can be obtained by adding a small amount of COS.

If the organic BARC 12 is etched using the COS gas produced by the above-described reaction, COS is adsorbed into the surfaces of the photoresist pattern 13 and the organic BARC 12 while forming a strong double bond like C═O═S or S═C═S thereon. Since the etching of the organic BARC 12 is performed by a physical etching as well as a chemical etching, the organic BARC 12 is etched by a physical force and a passivation layer 14 is formed on the surfaces of the photoresist pattern 13 and the organic BARC 12 at the same time.

The etching of the organic BARC 12 may be performed by plasma etching, especially in inductively coupled plasma (ICP) equipment. In addition, the etching of the organic BARC 12 may be performed at a temperature of approximately 10° C. to approximately 100° C. under a pressure of approximately 1 mTorr to approximately 100 mTorr.

When the organic BARC 12 is etched in the ICP equipment, a top power and a bottom power may be 13.56 MHz. In particular, a dual bottom power may be used by additionally supplying the bottom power of 100 MHz or less (e.g., 2 MHz, 13.56 MHz, 60 MHz).

The organic BARC 12 is etched to form an organic BARC pattern 12A. At this point, the passivation layer 14 is formed on the surfaces of the photoresist pattern 13 and the organic BARC pattern 12A by the sulfur-containing gas or the mixed gas of the sulfur-containing gas. That is, the passivation layer 14 is formed as the the organic BARC 12 is being etched, thereby preventing distortion and loss of the photoresist pattern 13.

Therefore, the use of the photoresist pattern 13 and the organic BARC pattern 12A as an etch barrier can prevent breaks, distortion or loss of the pattern in a subsequent process of etching the etch target layer 11. Furthermore, the pattern formed by the etching of the etch target layer 11 may be a gate, a bit line, or a metal interconnection in a dynamic random access memory (DRAM) and a nonvolatile memory. The pattern may also be a hard mask pattern for forming the gate, the bit line, or the metal interconnection. When the etch target layer 11 is a substrate, the pattern may be a device isolation layer. When the etch target layer 11 is a nitride layer, the pattern may be a hole or groove shaped concave portion (e.g., a via, a trench, or a combined structure thereof). Moreover, the pattern may be a spacer pattern technology (SPT) or double pattern technology (DPT) hard mask pattern. The pattern may be applied to all mask process of the semiconductor device using the photoresist pattern 13 and the organic BARC pattern 12A.

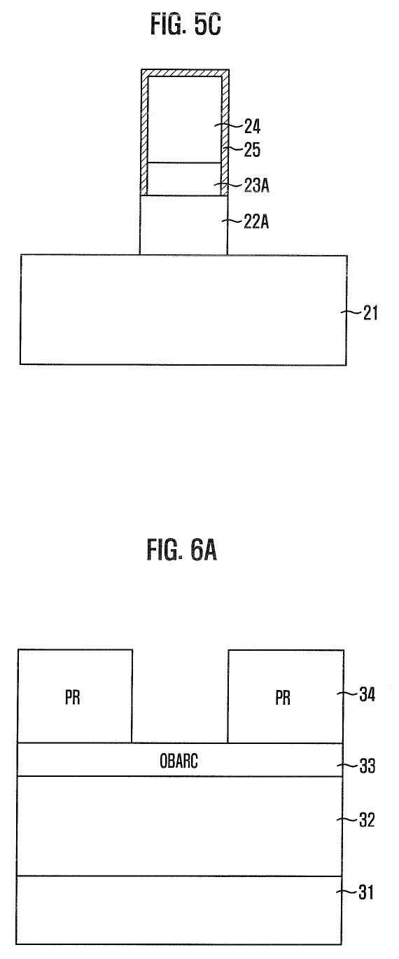

FIGS. 5A to 5C illustrate a method for fabricating a conductive pattern of a semiconductor device in accordance with a first embodiment of the present invention.

Referring to FIG. 5A, a conductive layer 22 and an organic BARC 23 are formed over a substrate 21. The substrate 21 may be a silicon substrate. The conductive layer 22 will be used as a conductive pattern and may be formed of polysilicon or metal. The organic BARC 23 serves to prevent reflection in an exposure process of a subsequent photoresist layer.

A photoresist pattern 24 is formed over the organic BARC 23. The photoresist pattern 24 may be formed by coating a photoresist layer over the organic BARC 23 and patterning the coated photoresist layer through exposure and development processes to define a pattern formation region.

Referring to FIG. 5B, the organic BARC 23 (see FIG. 5A) is etched using a sulfur-containing gas or a mixed gas of a sulfur-containing gas. At this point, the photoresist pattern 24 is used as an etch barrier. The sulfur-containing gas may include COS gas or SO₂ gas. The sulfur-containing gas may also include a mixed gas of SO₂ and O₂.

In the case of the SO₂ gas, sulfur (S) component of SO₂ reacts with the carbon-based photoresist pattern 24 and C═O═S or S═C═S bonding is formed on the surface of the photoresist pattern 24. In this case, a large amount of gas is needed because the COS or SCS bonding needs to be formed first when the photoresist pattern 24 reacts with SO₂.

In the case of the COS gas, the same effect as the case of the SO₂ gas can be obtained by using a small amount of gas, because the above reaction of the SO₂ gas is not needed. Therefore, the COS gas may be used as the sulfur-contained gas.

When the COS gas is used as the sulfur-containing gas, a mixed gas may include COS and one or more gases selected from the group consisting of SiCl₄, Ar, He, O₂, N₂, CO, Xe, and Kr in order to increase the etch efficiency. In order to reduce the LWR and the LER, HBr or Cl₂ may be further added to the mixed gas including COS and one or more gases selected from the group consisting of SiCl₄, Ar, He, O₂, N₂, CO, Xe, and Kr.

The COS gas used in etching the organic BARC 23 may be produced by the following reaction formula:

SO₂+3CO→COS+2CO₂

2CO+S₂→2COS

From the above reaction formula, COS may be produced through the reaction of SO₂ and 3CO or the reaction of 2CO and S₂. That is, since COS has been formed already, another reaction is not needed. Since COS can be adsorbed into the surface of the photoresist pattern 24, the protection effect of the photoresist pattern 24 can be obtained by adding a small amount of COS.

If the organic BARC 23 is etched using the COS gas produced by the above-described reaction, COS is adsorbed into the surfaces of the photoresist pattern 24 and the organic BARC 23 while forming a strong double bond like C═O═S or S═C═S thereon. Since the etching of the organic BARC 23 is performed by a physical etching as well as a chemical etching, the organic BARC 23 is etched by a physical force and a passivation layer 25 is formed on the surfaces of the photoresist pattern 24 and the organic BARC 23 at the same time.

The etching of the organic BARC 23 may be performed by plasma etching, especially in inductively coupled plasma (ICP) equipment. In addition, the etching of the organic BARC 23 may be performed at a temperature of approximately 10° C. to approximately 100° C. under a pressure of approximately 1 mTorr to approximately 100 mTorr.

When the organic BARC 23 is etched in the ICP equipment, a top power and a bottom power may be 13.56 MHz. In particular, a dual bottom power may be used by additionally supplying the bottom power of 100 MHz or less (e.g., 2 MHz, 13.56 MHz, 60 MHz).

The organic BARC 23 is etched to form an organic BARC pattern 23A. At this point, the passivation layer 25 is formed on the surfaces of the photoresist pattern 24 and the organic BARC pattern 23A by the sulfur-containing gas or the mixed gas of the sulfur-containing gas. That is, the passivation layer 25 is formed as the organic BARC 23 is being etched, thereby preventing distortion and loss of the photoresist pattern 24.

Referring to FIG. 5C, a conductive pattern 22A is formed by etching the conductive layer 22 using the photoresist pattern 24 and the organic BARC 23A as an etch barrier. The passivation layer 25 protects the surfaces of the photoresist pattern 24 and the organic BARC pattern 23A, thereby preventing the loss of the photoresist pattern 24 and sufficiently ensuring the etch margin in etching the conductive layer 22. Therefore, the breakage, distortion or loss of the conductive pattern 22A can be prevented.

The conductive pattern 22A may be a gate, a bit line, or a metal interconnection of a DRAM or a nonvolatile memory.

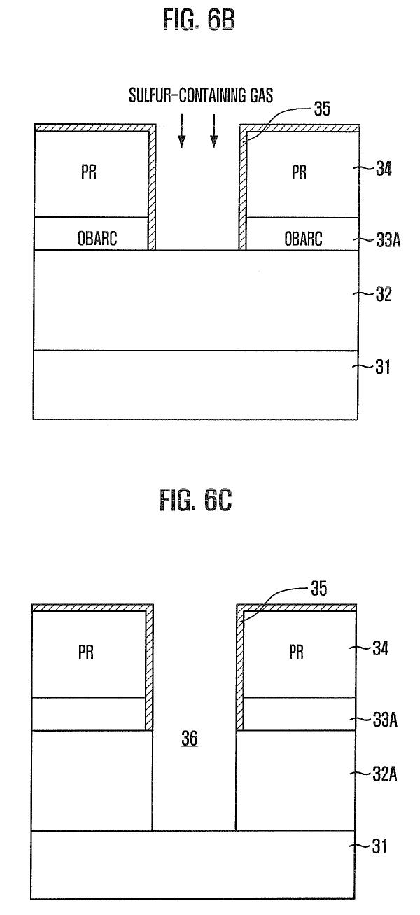

FIGS. 6A to 6C illustrate a method for fabricating a semiconductor device in accordance with a second embodiment of the present invention.

Referring to FIG. 6A, a nitride layer 32 and an organic BARC 33 are formed over a substrate 31. The substrate 31 may be a silicon substrate. The nitride layer 32 may be an oxide layer or a nitride layer for providing a hole or groove shaped concave structure (e.g., a via, a trench, or a combined structure thereof). The organic BARC 33 serves to prevent reflection in an exposure process of a subsequent photoresist layer.

A photoresist pattern 34 is formed over the organic BARC 33. The photoresist pattern 34 may be formed by coating a photoresist layer over the organic BARC 33 and patterning the coated photoresist layer through exposure and development processes to open a contact hole formation region.

Referring to FIG. 6B, the organic BARC 33 (see FIG. 6A) is etched using a sulfur-containing gas or a mixed gas of a sulfur-containing gas. At this point, the photoresist pattern 34 is used as an etch barrier. The sulfur-containing gas may include COS gas or SO₂ gas. The sulfur-containing gas may also include a mixed gas of SO₂ and O₂.

In the case of the SO₂ gas, sulfur (S) component of SO₂ reacts with the carbon-based photoresist pattern 34 and C═O═S or S═C═S bonding is formed on the surface of the photoresist pattern 34. In this case, a large amount of gas is needed because the COS or SCS bonding needs to be formed first when the photoresist pattern 34 reacts with SO₂.

In the case of the COS gas, the same effect as the case of the SO₂ gas can be obtained by using a small amount of gas, because the above reaction of the SO₂ gas is not needed. Therefore, the COS gas may be used as the sulfur-contained gas.

When the COS gas is used as the sulfur-containing gas, a mixed gas may include COS and one or more gases selected from the group consisting of SiCl₄, Ar, He, O₂, N₂, CO, Xe, and Kr in order to increase the etch efficiency. In order to reduce the LWR and the LER, HBr or Cl₂ may be further added to the mixed gas including COS and one or more gases selected from the group consisting of SiCl₄, Ar, He, O₂, N₂, CO, Xe, and Kr.

The COS gas used in etching the organic BARC 33 may be produced by the following reaction formula:

SO₂+3CO→COS+2CO₂

2CO+S₂→2COS

From the above reaction formula, COS may be produced through the reaction of SO₂ and 3CO or the reaction of 2CO and S₂. That is, since COS has been already bonded, another reaction is not needed. Since COS can be adsorbed into the surface of the photoresist pattern 34, the protection effect of the photoresist pattern 34 can be obtained by adding a small amount of COS.

If the organic BARC 33 is etched using the COS gas produced by the above-described reaction, COS is adsorbed into the surfaces of the photoresist pattern 34 and the organic BARC 33 while forming a strong double bond like C═O═S or S═C═S thereon. Since the etching of the organic BARC 33 is performed by a physical etching as well as a chemical etching, the organic BARC 33 is etched by a physical force and a passivation layer 35 is formed on the surfaces of the photoresist pattern 34 and the organic BARC 33 at the same time.

The etching of the organic BARC 33 may be performed by plasma etching, especially in inductively coupled plasma (ICP) equipment. In addition, the etching of the organic BARC 33 may be performed at a temperature of approximately 10° C. to approximately 100° C. under a pressure of approximately 1 mTorr to approximately 100 mTorr.

When the organic BARC 33 is etched in the ICP equipment, a top power and a bottom power may be 13.56 MHz. In particular, a dual bottom power may be used by additionally supplying the bottom power of 100 MHz or less (e.g., 2 MHz, 13.56 MHz, 60 MHz).

The organic BARC 33 is etched to form an organic BARC pattern 33A. At this point, the passivation layer 35 is formed on the surfaces of the photoresist pattern 34 and the organic BARC pattern 33A by the sulfur-containing gas or the mixed gas of the sulfur-containing gas. That is, the passivation layer 35 is formed as the organic BARC 33 is being etched, thereby preventing distortion and loss of the photoresist pattern 34.

Referring to FIG. 6C, a concave portion 36 is formed by etching the nitride layer 32 (see FIG. 6B) using the photoresist pattern 34 and the organic BARC pattern 33A as an etch barrier. The etched nitride layer 32 becomes a nitride pattern 32A defining the concave portion 36.

The passivation layer 35 protects the surfaces of the photoresist pattern 34 and the organic BARC pattern 33A, thereby preventing the loss of the photoresist pattern 34 and sufficiently ensuring the etch margin in etching the nitride layer 32. Therefore, the distortion or not-open failure of the concave portion 36 can be prevented.

The concave portion 36 is a hole or groove shaped concave portion and may be a via, a trench, or a combined structure thereof. Moreover, the concave portion 36 may include all concave structures applied to a semiconductor device.

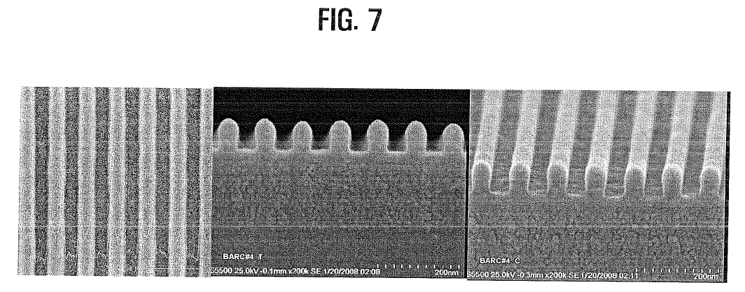

FIG. 7 illustrates photographs of the photoresist pattern in etching an organic BARC according to the embodiment of the present invention.

Referring to FIG. 7, the loss of the photoresist pattern can be prevented by the COS gas and the photoresist pattern has a vertical profile at its sidewalls. Furthermore, the photoresist pattern can be uniform without distortion.

In accordance with the embodiments of the present invention, the photoresist pattern can be protected from loss and damage by etching the organic BARC using the sulfur-containing gas or the mixed gas of the sulfur-containing gas.

Therefore, the distortion, breaks and loss of the pattern can be prevented in a subsequent process of forming the BARC pattern using the photoresist pattern as a mask. When the pattern is a concave portion, not-open failure can be prevented.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, the method comprising:
forming an organic bottom anti-reflective coating over an etch target layer;
forming a photoresist pattern over the organic bottom anti-reflective coating; and
etching the organic bottom anti-reflective coating using an etchant including sulfur.

2. The method of claim 1, wherein the etchant comprises COS gas.

3. The method of claim 1, wherein the organic bottom anti-reflective coating is etched using plasma etching.

4. The method of claim 3, wherein the organic bottom anti-reflective coating is etched in an inductively coupled plasma (ICP) equipment.

5. The method of claim 1, wherein the organic bottom anti-reflective coating is etched at a temperature of no more than 100° C.

6. The method of claim 1, wherein the organic bottom anti-reflective coating is etched at a pressure of approximately 1 mTorr to approximately 100 mTorr.

7. The method of claim 1, wherein the etch target layer comprises a nitride layer or a conductive layer.

8. A method for fabricating a semiconductor device, the method comprising:
forming an organic bottom anti-reflective coating over an etch target layer;
forming a photoresist pattern over the organic bottom anti-reflective coating; and
etching the organic bottom anti-reflective coating using a mixed gas including a sulfur-containing gas.

9. The method of claim 1, wherein the sulfur-containing gas comprises COS.

10. The method of claim 9, wherein etching the organic bottom anti-reflective coating is performed using a mixed gas comprising COS and one or more gases selected from the group consisting of tetrachlorosilane (SiCl₄), argon (Ar), helium (He), O₂, N₂, carbon monoxide (CO), xenon (Xe), and krypton (Kr).

11. The method of claim 10, wherein etching the organic bottom anti-reflective coating is performed using a gas where hydrogen bromide (HBR) or chlorine (Cl₂), or both, is added to the mixed gas.

12. The method of claim 8, wherein etching the organic bottom anti-reflective coating is performed by a mixed gas including sulfur dioxide (SO₂) and O₂.

13. The method of claim 8, wherein the organic bottom anti-reflective coating is etched using plasma etching.

14. The method of claim 13, wherein the organic bottom anti-reflective coating is etching in an inductively coupled plasma (ICP) equipment.

15. The method of claim 8, wherein the organic bottom anti-reflective coating is etched at a temperature of no more than 100° C.

16. The method of claim 8, wherein the organic bottom anti-reflective coating is etched at a pressure of approximately 1 mTorr to approximately 100 mTorr.

17. The method of claim 1, wherein the etch target layer comprises a nitride layer or a conductive layer.
